(19) United States
(12) Patent Application Publication
(10) Pub. No.: US 2026/0075855 A1
(43) Pub. Date: Mar. 12, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Ryohei GEJO, Kawasaki Kanagawa (JP); Tatsunori SAKANO, Shinagawa Tokyo (JP); Yusuke KOBAYASHI, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/254,141

(22) Filed: Jun. 30, 2025

(30) Foreign Application Priority Data
Sep. 9, 2024 (JP) 2024-155057

(51) Int. Cl. H10D 12/00; H10D 62/10

(52) U.S. Cl. CPC H10D 12/481; H10D 12/415; H10D 62/109

(57) ABSTRACT

According to one embodiment, a semiconductor device includes first to fourth electrodes, first and second terminals, a semiconductor member, and a first insulating member. The semiconductor member includes a first semiconductor region of a first conductivity type, a second semiconductor region of a second conductivity type, a third semiconductor region of the first conductivity type, a fourth semiconductor region of the second conductivity type, and a fifth semiconductor region of the second conductivity type. The first insulating member includes a first insulating region and a second insulating region. The first insulating region is between the third electrode and the semiconductor member. The second insulating region is between the fourth electrode and the semiconductor member.

### CROSS-REFERENCE TO RELATED APPLICATIONS

This application is based upon and claims the benefit of priority from Japanese Patent Application No. 2024-155057, filed on Sep. 9, 2024; the entire contents of which are incorporated herein by reference.

### FIELD

Embodiments described herein relate generally to a semiconductor device.

### BACKGROUND

For example, in semiconductor devices, improvements in characteristics are desired.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to the first embodiment;

FIG. 4 is a schematic cross-sectional view illustrating a semiconductor device according to the first embodiment;

FIG. 5 is a schematic cross-sectional view illustrating a semiconductor device according to the first embodiment;

FIG. 6 is a schematic cross-sectional view illustrating a semiconductor device according to the first embodiment;

FIG. 7 is a schematic cross-sectional view illustrating a semiconductor device according to the first embodiment;

FIG. 8 is a schematic cross-sectional view illustrating a semiconductor device according to the first embodiment;

FIG. 9 is a schematic cross-sectional view illustrating a semiconductor device according to the first embodiment; and

FIG. 10 is a schematic cross-sectional view illustrating a semiconductor device according to a second embodiment.

### DETAILED DESCRIPTION

According to one embodiment, a semiconductor device includes a first electrode, a second electrode, a third electrode, a fourth electrode, a first terminal, a second terminal, a semiconductor member, and a first insulating member. A second direction from the third electrode to the fourth electrode crosses a first direction from the first electrode to the second electrode. The first terminal is electrically connected to the third electrode. The second terminal is electrically connected to the fourth electrode. At least a part of the semiconductor member is between the first electrode and the second electrode in the first direction. The semiconductor member includes a first semiconductor region of a first conductivity type, a second semiconductor region of a second conductivity type, a third semiconductor region of the first conductivity type, a fourth semiconductor region of the second conductivity type, and a fifth semiconductor region of the second conductivity type. The fourth semiconductor region is between the first electrode and the first semiconductor region in the first direction. The second semiconductor region is between the first semiconductor region and the second electrode in the first direction. The first semiconductor region includes a first partial region, a second partial region, a third partial region, and a fourth partial region. The first partial region is between the first electrode and the third electrode in the first direction. A direction from the third electrode to the second partial region is along the second direction. A direction from the third electrode to the second semiconductor region is along the second direction. A direction from the third electrode to the third semiconductor region is along the second direction. At least a part of the second semiconductor region is between the first semiconductor region and the third semiconductor region in the first direction. The fifth semiconductor region is between the first partial region and the third electrode in the first direction. The third partial region is between the first electrode and the fourth electrode in the first direction. The direction from the fourth electrode to the fourth partial region is along the second direction, The direction from the fourth electrode to the second semiconductor region is along the second direction. The first insulating member includes a first insulating region and a second insulating region. The first insulating region is between the third electrode and the semiconductor member. The second insulating region is between the fourth electrode and the semiconductor member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

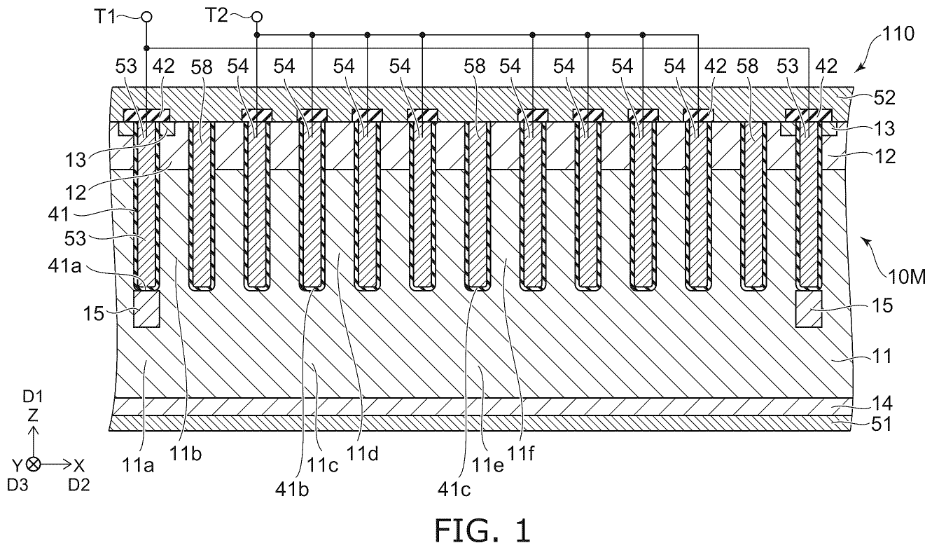

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a fourth electrode 54, a first terminal T1, a second terminal T2, a semiconductor member 10M, and a first insulating member 41.

A second direction D2 from the third electrode 53 to the fourth electrode 54 crosses a first direction D1 from the first electrode 51 to the second electrode 52.

The first direction D1 is defined as a Z-axis direction. One direction perpendicular to the Z-axis direction is defined as an X-axis direction. A direction perpendicular to the Z-axis and X-axis directions is defined as a Y-axis direction. The second direction D2 may be, for example, the X-axis direction.

The third electrode 53 and the fourth electrode 54 may extend along a third direction D3. The third direction D3 may be, for example, the Y-axis direction. A plurality of third electrodes 53 may be provided. A direction from one of the plurality of third electrodes 53 to another one of the plurality of third electrodes 53 is along the second direction D2. A plurality of fourth electrodes 54 may be provided. A direction from one of the plurality of fourth electrodes 54 to another one of the plurality of fourth electrodes 54 is along the second direction D2.

The first terminal T1 is electrically connected to the third electrode 53. The second terminal T2 is electrically connected to the fourth electrode 54. The first terminal T1 may be electrically connected to the plurality of third electrodes 53. The second terminal T2 may be electrically connected to the plurality of fourth electrodes 54. Below, one of the plurality of third electrodes 53 and one of the plurality of fourth electrodes 54 will be described.

At least a part of the semiconductor member 10M is provided between the first electrode 51 and the second electrode 52 in the first direction D1. The semiconductor member 10M includes a first semiconductor region 11 of a first conductivity type, a second semiconductor region 12 of a second conductivity type, a third semiconductor region 13 of the first conductivity type, a fourth semiconductor region 14 of the second conductivity type, and a fifth semiconductor region 15 of the second conductivity type.

For example, the first conductivity type is of n-type and the second conductivity type is of p-type. The first conductivity type may be of p-type and the second conductivity type may be of n-type. In the following, the first conductivity type is of n-type and the second conductivity type is of p-type.

The fourth semiconductor region 14 is located between the first electrode 51 and the first semiconductor region 11 in the first direction D1. The second semiconductor region 12 is located between the first semiconductor region 11 and the second electrode 52 in the first direction D1.

The first semiconductor region 11 includes a first partial region 11a, a second partial region 11b, a third partial region 11c, and a fourth partial region 11d. The first partial region 11a is located between the first electrode 51 and the third electrode 53 in the first direction D1. A direction from the third electrode 53 to the second partial region 11b is along the second direction D2.

A direction from the third electrode 53 to the second semiconductor region 12 is along the second direction D2. A direction from the third electrode 53 to the third semiconductor region 13 is along the second direction D2. At least a part of the second semiconductor region 12 is located between the first semiconductor region 11 and the third semiconductor region 13 in the first direction D1. For example, the third semiconductor region 13 is located between the third electrode 53 and a part of the second semiconductor region 12 in the second direction D2. The fifth semiconductor region 15 is located between the first partial region 11a and the third electrode 53 in the first direction D1.

The third partial region 11c is located between the first electrode 51 and the fourth electrode 54 in the first direction D1. A direction from the fourth electrode 54 to the fourth partial region 11d is along the second direction D2. A direction from the fourth electrode 54 to the second semiconductor region 12 is along the second direction D2. The boundaries between the first partial region 11a, the second partial region 11b, the third partial region 11c, and the fourth partial region 11d may be clear or unclear.

The first insulating member 41 includes a first insulating region 41a and a second insulating region 41b. The first insulating region 41a is located between the third electrode 53 and the semiconductor member 10M. The second insulating region 41b is located between the fourth electrode 54 and the semiconductor member 10M.

Current flowing between the first electrode 51 and the second electrode 52 can be controlled by a potential of the third electrode 53. The potential of the third electrode 53 may be a potential based on a potential of the second electrode 52. The first electrode 51 functions as a collector electrode, for example. The second electrode 52 functions as an emitter electrode, for example. The third electrode 53 functions as a gate electrode, for example. The semiconductor device is, for example, an IGBT (Insulated Gate Bipolar Transistor).

A first signal is input to the first terminal T1 electrically connected to the third electrode 53. In the semiconductor device 110, a second terminal T2 electrically connected to the fourth electrode 54 is provided. The second signal input to the second terminal T2 may be different from the first signal. For example, the on/off timing of the second signal may be different from the on/off timing of the first signal. By using signals with different timings, for example, losses can be effectively suppressed. The fourth electrode 54 may function as, for example, a control gate electrode. The semiconductor device 110 is, for example, a double-gate IGBT.

In the embodiment, the fifth semiconductor region 15 is provided in correspondence with the third electrode 53. Thereby, it becomes possible, for example, to suppress localized electric field concentration. Thereby, the turn-off capability is improved, for example, when switching is performed at high speed. For example, when switching is performed with a large current, the turn-off capability is improved.

In a first reference example, a semiconductor region of the second conductivity type is provided not only under the third electrode 53 but also under the fourth electrode 54. In this first reference example, it has been found that when the fourth electrode 54 is switched on and off, loss increases. This is thought to be because excessive extraction of holes occurs when the fourth electrode 54 is turned off.

In the embodiment, the fifth semiconductor region 15 is provided corresponding to the third electrode 53, and the fifth semiconductor region 15 is not provided below the fourth electrode 54. This makes it possible to suppress losses caused by the excessive extraction of holes. Furthermore, the fifth semiconductor region 15 corresponding to the third electrode 53 suppresses electric field concentration, improving the turn-off capability. According to the embodiment, it is possible to improve the turn-off capability while suppressing an increase in loss. According to the embodiment, it is possible to provide a semiconductor device that can improve characteristics.

As described below, when a plurality of fourth electrodes 54 are provided, a semiconductor region of the second conductivity type may be provided below a part of the plurality of fourth electrodes 54, and a semiconductor region of the second conductivity type may not be provided below another part of the plurality of fourth electrodes 54.

In the example shown in FIG. 1, no semiconductor region of the second conductivity type is provided below any of the plurality of fourth electrodes 54. For example, the second insulating region 41b contacts the third partial region 11c and the fourth electrode 54 in the first direction D1.

As already explained, the third semiconductor region 13 is provided between the third electrode 53 and the second semiconductor region 12. The third semiconductor region 13 may not be provided between the fourth electrode 54 and the second semiconductor region 12.

An impurity concentration of the second conductivity type in the fifth semiconductor region 15 (fifth impurity concentration) may be not less than 0.001 times and not more than 0.1 times than an impurity concentration of the second conductivity type in the second semiconductor region 12 (second impurity concentration). In one example, the fifth impurity concentration may be not less than 1.0×10¹⁴ cm⁻³ and not more than 1.0×10¹⁶ cm⁻³. The second impurity concentration may be not less than 1.0×10¹⁷ cm⁻³ and not more than 1.0×10¹⁸ cm^{-3.}

The second electrode 52 is electrically connected to the third semiconductor region 13. An impurity concentration of the first conductivity type in the third semiconductor region 13 (third impurity concentration) is higher than an impurity concentration of the first conductivity type in the first semiconductor region 11 (first impurity concentration). The first impurity concentration is, for example, not less than 1.0×10¹² cm⁻³ and not more than 1.0×10¹⁵ cm⁻³. The third impurity concentration is, for example, not less than 1.0×10¹⁹ cm⁻³ and not more than 1.0×10²¹ cm^{-3.}

An impurity concentration of the second conductivity type in the fourth semiconductor region 14 may be, for example, not less than 1.0×10¹⁷ cm⁻³ and not more than 1.0×10¹⁹ cm^{-3.}

As shown in FIG. 1, the semiconductor device 110 may further include a second insulating member 42. At least a part of the second insulating member 42 is provided between the third electrode 53 and the second electrode 52, and between the fourth electrode 54 and the second electrode 52.

The semiconductor device 110 may further include a first conductive member 58. A direction from the third electrode 53 to the first conductive member 58 is along the second direction D2. The first semiconductor region 11 further includes a fifth partial region 11e and a sixth partial region 11f. The fifth partial region 11e is located between the first electrode 51 and the first conductive member 58 in the first direction D1. A direction from the first conductive member 58 to the sixth partial region 11f is along the second direction D2.

A direction from the first conductive member 58 to the second semiconductor region 12 is along the second direction D2. The first insulating member 41 includes a third insulating region 41c. The third insulating region 41c is located between the first conductive member 58 and the semiconductor member 10M. The first conductive member 58 is electrically connected to the second electrode 52. The first conductive member 58 is, for example, a dummy gate. The first conductive member 58 may not contribute to switching.

The third electrode 53, the fourth electrode 54, and the first conductive member 58 are each formed by filling a trench provided in the semiconductor member 10M with a conductive material. Before forming the conductive material, the first insulating member 41 may be formed by forming an insulating film on the inner surface of the trench. The fifth semiconductor region 15 may be formed by introducing an impurity into a portion including the bottom of the target trench.

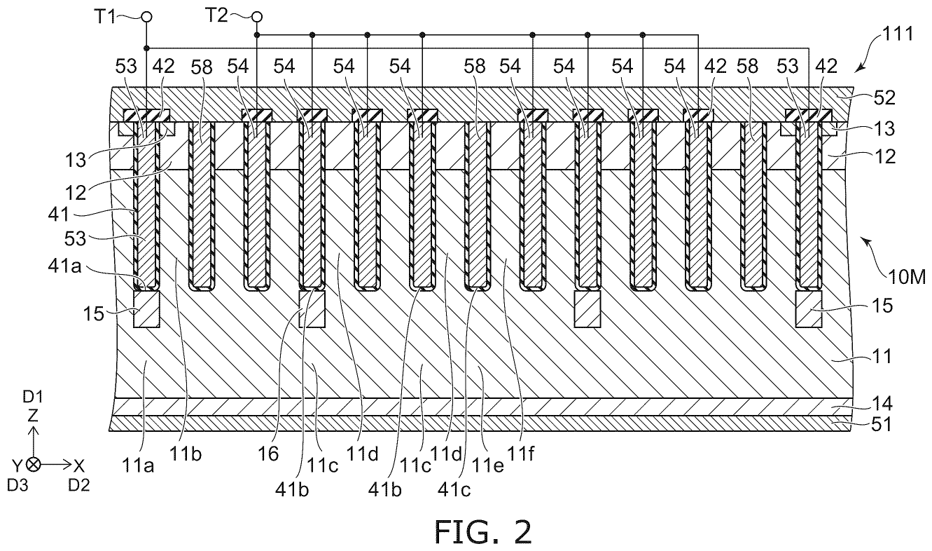

FIG. 2 is a schematic cross-sectional view illustrating a semiconductor device according to the first embodiment.

As shown in FIG. 2, in a semiconductor device 111 according to the embodiment, a sixth semiconductor region 16 is provided. Except for this, the configuration of the semiconductor device 111 may be the same as the configuration of the semiconductor device 110.

In the semiconductor device 111, a plurality of fourth electrodes 54 are provided. The sixth semiconductor region 16 is provided below a part of the plurality of fourth electrodes 54. The first semiconductor region 11 includes a plurality of third partial regions 11c. One of the plurality of third partial regions 11c is located between the first electrode 51 and one of the plurality of fourth electrodes 54 in the first direction D1. Another one of the plurality of third partial regions 11c is located between the first electrode 51 and another one of the plurality of fourth electrodes 54 in the first direction D1.

The semiconductor member 10M further includes a sixth semiconductor region 16 of the second conductivity type. The sixth semiconductor region 16 is located between the one of the plurality of third partial regions 11c and the one of the plurality of fourth electrodes 54 in the first direction D1. The sixth semiconductor region 16 is not provided between another one of the plurality of third partial regions 11c and another one of the plurality of fourth electrodes 54. For example, the second insulating region 41b contacts the other one of the plurality of fourth electrodes 54 and the first semiconductor region 11 in the first direction D1.

Thus, when the plurality of fourth electrodes 54 are provided, the sixth semiconductor region 16 may be provided in correspondence with a part of the plurality of fourth electrodes 54. In the semiconductor device 111, loss caused by the excessive extraction of holes when the fourth electrode 54 is off can also be suppressed. A semiconductor device with improved characteristics can be provided.

The impurity concentration of the second conductivity type in the fifth semiconductor region 15 (fifth impurity concentration) may be higher than an impurity concentration of the second conductivity type in the sixth semiconductor region 16 (sixth impurity concentration). Thereby, it becomes easier to suppress electric field concentration in the first partial region 11a. The sixth impurity concentration may be, for example, not less than 1.0×10¹⁴ cm⁻³ and not more than 1.0×10¹⁶ cm^{-3.}

The sixth semiconductor region 16 may be formed by introducing impurities into a part of the target trench that includes the bottom.

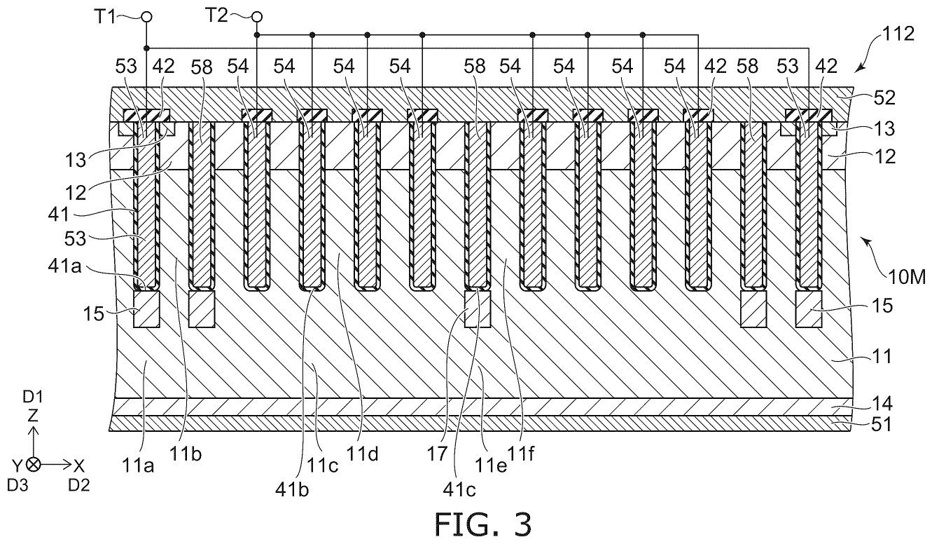

FIG. 3 is a schematic cross-sectional view illustrating a semiconductor device according to the first embodiment.

As shown in FIG. 3, in a semiconductor device 112 according to the embodiment, a seventh semiconductor region 17 is provided. Except for this, the configuration of the semiconductor device 112 may be the same as the configuration of the semiconductor device 110.

As shown in FIG. 3, the first conductive member 58 is provided. The semiconductor member 10M further includes the seventh semiconductor region 17 of the second conductivity type. The seventh semiconductor region 17 is located between the fifth partial region 11e and the first conductive member 58. In the semiconductor device 112, loss caused by the excessive extraction of holes when the fourth electrode 54 is off can also be suppressed. A semiconductor device with improved characteristics can be provided.

The impurity concentration of the second conductivity type in the fifth semiconductor region 15 (sixth impurity concentration) may be higher than an impurity concentration of the second conductivity type in the seventh semiconductor region 17 (seventh impurity concentration). Thereby, it becomes easier to suppress electric field concentration in the first partial region 11a. The seventh impurity concentration may be, for example, not less than 1.0×10¹⁴ cm⁻³ and not more than 1.0×10¹⁶ cm^{-3.}

The seventh semiconductor region 17 may be formed by introducing an impurity into a part of the target trench that includes the bottom of the trench.

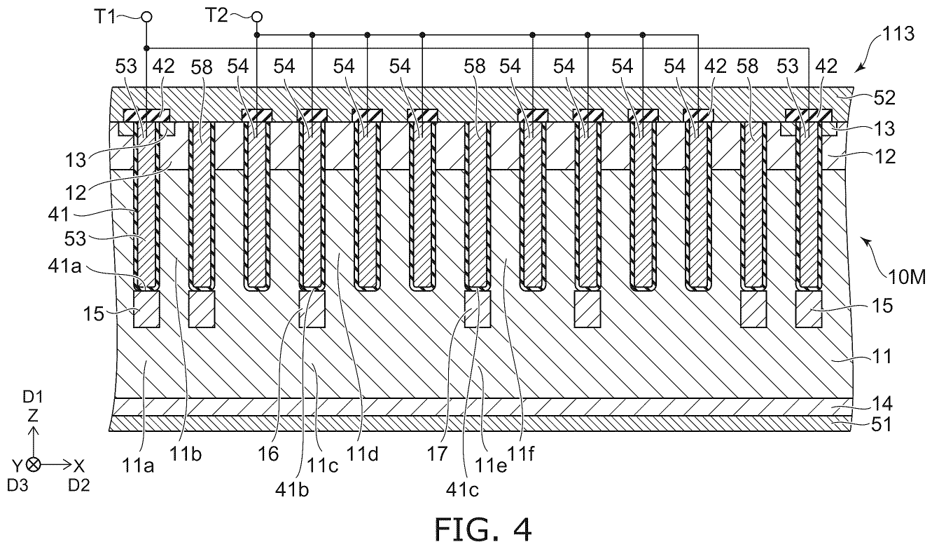

FIG. 4 is a schematic cross-sectional view illustrating a semiconductor device according to the first embodiment.

As shown in FIG. 4, in a semiconductor device 113 according to the embodiment, the sixth semiconductor region 16 and the seventh semiconductor region 17 are provided. Except for this, the configuration of the semiconductor device 113 may be the same as the configuration of the semiconductor device 110, etc.

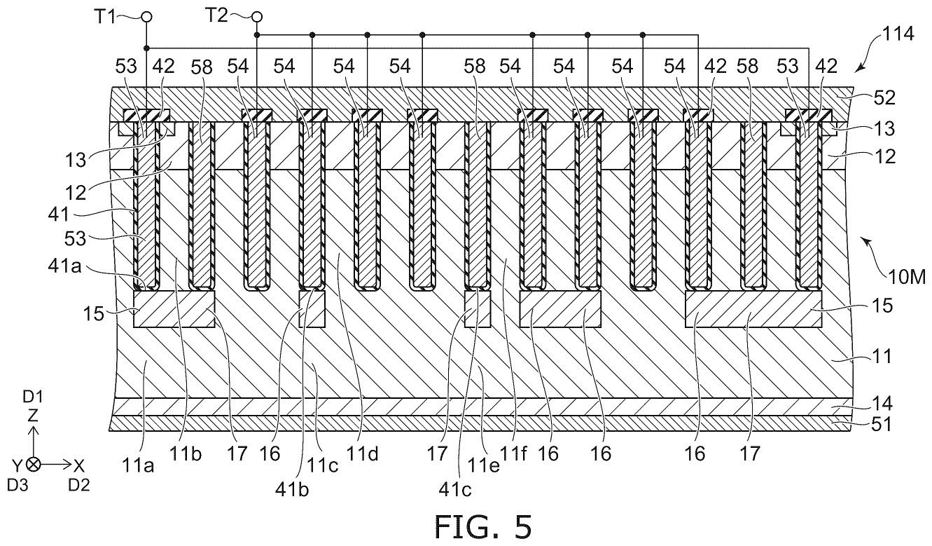

FIG. 5 is a schematic cross-sectional view illustrating a semiconductor device according to the first embodiment.

As shown in FIG. 5, in a semiconductor device 114 according to the embodiment, the shape of the fifth semiconductor region 15 is different from that in the semiconductor device 113. Except for this, the configuration of the semiconductor device 114 may be the same as the configuration of the semiconductor device 113.

In the semiconductor device 114, the seventh semiconductor region 17 is continuous with the fifth semiconductor region 15. The sixth semiconductor region 16 may also be continuous with the fifth semiconductor region 15. For example, this may facilitate manufacturing.

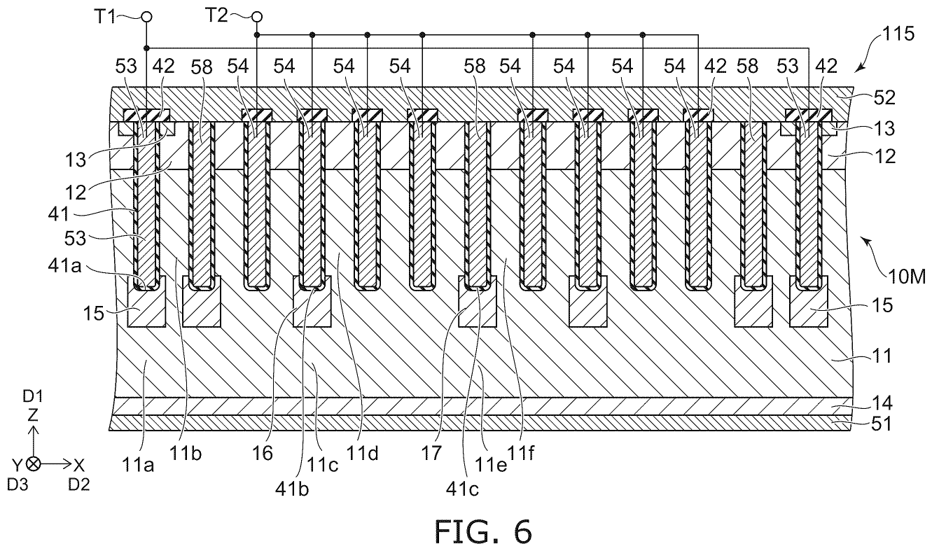

FIG. 6 is a schematic cross-sectional view illustrating a semiconductor device according to the first embodiment.

As shown in FIG. 6, in a semiconductor device 115 according to the embodiment, the shape of the fifth semiconductor region 15 differs from that in the semiconductor device 113. Except for this, the configuration of the semiconductor device 115 may be the same as the configuration of the semiconductor device 113.

In the semiconductor device 115, a part of the third electrode 53 is located between a part of the fifth semiconductor region 15 and another part of the fifth semiconductor region 15 in the second direction D2. Thereby, the turn-off capability can be improved more stably.

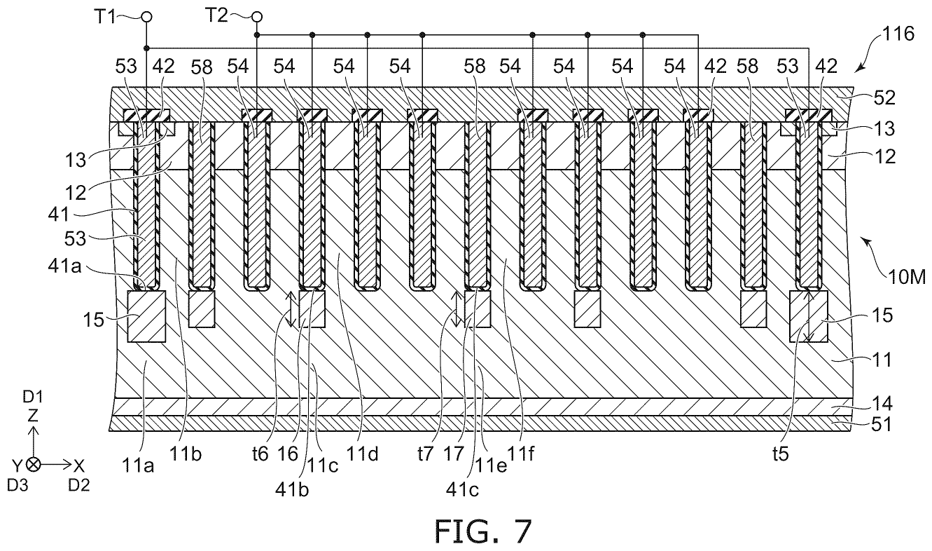

FIG. 7 is a schematic cross-sectional view illustrating a semiconductor device according to the first embodiment.

As shown in FIG. 7, in a semiconductor device 116 according to the embodiment, the shape of the fifth semiconductor region 15 differs from that in the semiconductor device 113. Except for this, the configuration of the semiconductor device 116 may be the same as the configuration of the semiconductor device 113.

In the semiconductor device 116, a thickness of the fifth semiconductor region 15 along the first direction D1 is defined as a fifth semiconductor region thickness t5. A thickness of the sixth semiconductor region 16 along the first direction D1 is defined as a sixth semiconductor region thickness t6. The fifth semiconductor region thickness t5 may be thicker than the sixth semiconductor region thickness t6. Thereby, the turn-off capability can be improved more stably.

A thickness of the seventh semiconductor region 17 along the first direction D1 is defined as a seventh semiconductor region thickness t7. The fifth semiconductor region thickness t5 of the fifth semiconductor region 15 along the first direction D1 may be thicker than the seventh semiconductor region thickness t7. Thereby, the turn-off capability can be improved more stably.

In the examples of semiconductor devices 110 to 116, the fifth semiconductor region 15 contacts the first insulating region 41a. In this manner, the first insulating region 41a may contact the fifth semiconductor region 15 and the third electrode 53.

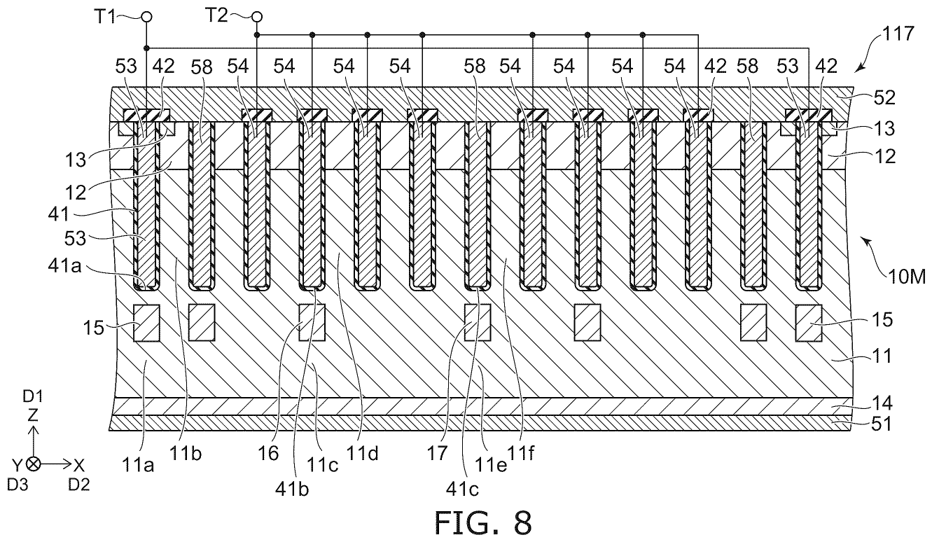

FIG. 8 is a schematic cross-sectional view illustrating a semiconductor device according to the first embodiment.

As shown in FIG. 8, in a semiconductor device 117 according to the embodiment, the configuration of the fifth semiconductor region 15 differs from that in the semiconductor device 113. Except for this, the configuration of the semiconductor device 117 may be the same as the configuration of the semiconductor device 113.

In the semiconductor device 117, the fifth semiconductor region 15 is separated from the first insulating region 41a. A part of the first semiconductor region 11 is provided between the fifth semiconductor region 15 and the first insulating region 41a in the first direction D1. In the semiconductor device 117 also, the loss caused by the excessive extraction of holes when the fourth electrode 54 is off can be more stably suppressed. The turn-off capability can be improved. A semiconductor device with improved characteristics can be provided.

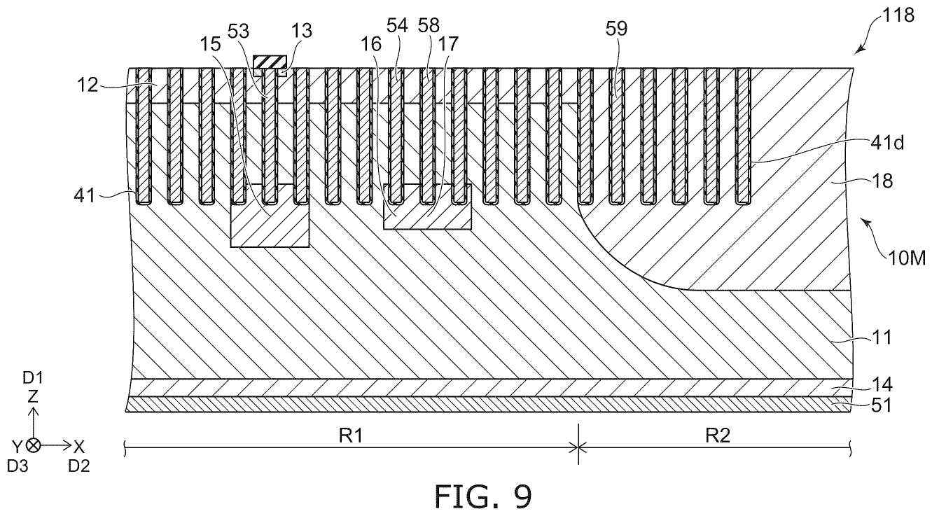

FIG. 9 is a schematic cross-sectional view illustrating a semiconductor device according to the first embodiment.

As shown in FIG. 9, in a semiconductor device 118 according to the embodiment, a cell region R1 and a peripheral region R2 are provided. Except for this, the configuration of semiconductor device 118 may be the same as the configurations of semiconductor devices 110 to 117.

In the semiconductor device 118, the semiconductor member 10M includes the cell region R1 and the peripheral region R2. A direction from the cell region R1 to the peripheral region R2 crosses the first direction D1. The third electrode 53 and the fourth electrode 54 are provided in the cell region R1.

The peripheral region R2 corresponds to, for example, a termination region. The peripheral region R2 corresponds to, for example, a guard ring region. The semiconductor device 118 may further include a second conductive member 59. The second conductive member 59 is provided in the peripheral region R2.

The semiconductor member 10M further includes an eighth semiconductor region 18 of the second conductivity type. In the peripheral region R2, a part of the first semiconductor region 11 is provided between the first electrode 51 and the eighth semiconductor region 18 in the first direction D1. A direction from the second conductive member 59 to the eighth semiconductor region 18 crosses the first direction D1. The second conductive member 59 is located between a part of the eighth semiconductor region 18 and another part of the eighth semiconductor region 18.

The first insulating member 41 further includes a fourth insulating region 41d. The fourth insulating region 41d is provided between the second conductive member 59 and the semiconductor member 10M.

The fifth semiconductor region 15 is discontinuous with the eighth semiconductor region 18. For example, a part of the first semiconductor region 11 is provided between the fifth semiconductor region 15 and the eighth semiconductor region 18. With this configuration, for example, holes in the cell region R1 can be prevented from being extracted to the outside via the peripheral region R2. For example, the potential of the fifth semiconductor region 15 may be floating.

The sixth semiconductor region 16 may be discontinuous with the eighth semiconductor region 18. The seventh semiconductor region 17 may be discontinuous with the eighth semiconductor region 18.

### Second Embodiment

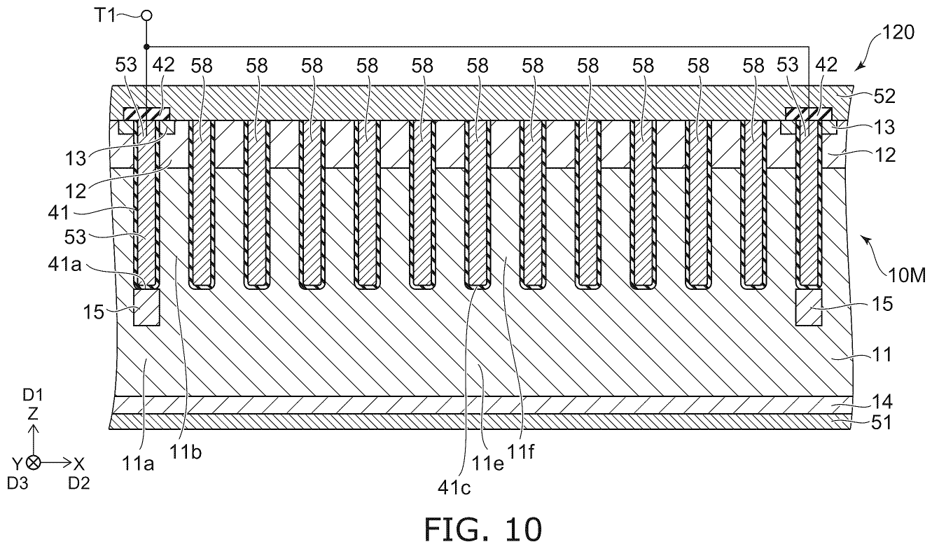

FIG. 10 is a schematic cross-sectional view illustrating a semiconductor device according to a second embodiment.

As shown in FIG. 10, a semiconductor device 120 according to the embodiment includes the first electrode 51, the second electrode 52, the third electrode 53, the semiconductor member 10M, and the first insulating member 41.

At least a part of the semiconductor member 10M is located between the first electrode 51 and the second electrode 52 in the first direction D1. The semiconductor member 10M includes the first semiconductor region 11 of the first conductivity type, the second semiconductor region 12 of the second conductivity type, the third semiconductor region 13 of the first conductivity type, the fourth semiconductor region 14 of the second conductivity type, and the fifth semiconductor region 15 of the second conductivity type.

The fourth semiconductor region 14 is provided between the first electrode 51 and the first semiconductor region 11 in the first direction D1. The second semiconductor region 12 is provided between the first semiconductor region 11 and the second electrode 52 in the first direction D1.

The first semiconductor region 11 includes the first partial region 11a and the second partial region 11b. The first partial region 11a is located between the first electrode 51 and the third electrode 53 in the first direction D1. The direction from the third electrode 53 to the second partial region 11b is along the second direction D2. The second direction D2 crosses the first direction D1.

The direction from the third electrode 53 to the second semiconductor region 12 is along the second direction D2. The direction from the third electrode 53 to the third semiconductor region 13 is along the second direction D2. At least a part of the second semiconductor region 12 is located between the first semiconductor region 11 and the third semiconductor region 13 in the first direction D1. For example, the third semiconductor region 13 is located between the third electrode 53 and a part of the second semiconductor region 12 in the second direction D2.

The first insulating member 41 includes the first insulating region 41a. The first insulating region 41a is located between the third electrode 53 and the semiconductor member 10M.

A plurality of third electrodes 53 are provided. The direction from one of the plurality of third electrodes 53 to another of the plurality of third electrodes 53 is along the second direction D2. The fifth semiconductor region 15 is provided between the first partial region 11a and the third electrode 53 in all of the plurality of third electrodes 53. For example, concentration of the electric field is suppressed. Losses can be reduced. Characteristics can be improved.

The semiconductor device 110 may further include a plurality of first conductive members 58. The direction from the third electrode 53 to the plurality of first conductive members 58 is along the second direction D2. The first semiconductor region 11 further includes the fifth partial region 11e and the sixth partial region 11f. The fifth partial region 11e is located between the first electrode 51 and the first conductive members 58 in the first direction D1. The direction from the first conductive members 58 to the sixth partial region 11f is along the second direction D2.

The fifth semiconductor region 15 is not provided between the fifth partial region 11e and the first conductive member 58 in any of the multiple first conductive members 58.

In the embodiment, at least one of the first electrode 51 or the second electrode 52 may include a metal. The metal may include at least one selected from the group consisting of Al, Ti, Ni, Au, Ag, and Cu. At least one of the third electrode 53, the fourth electrode 54, the first conductive member 58, or the second conductive member 59 may include polysilicon. The semiconductor member 10M may include silicon. The semiconductor member 10M may include a compound semiconductor. The compound semiconductor may include at least one selected from the group consisting of SiC, GaN, GaO, and GaAs.

In the embodiment, information regarding the shape of the semiconductor member is obtained, for example, from an electron microscope image. Information regarding the composition and element concentration is obtained, for example, from EDX (Energy Dispersive X-ray Spectroscopy) or SIMS (Secondary Ion Mass Spectrometry). Information regarding the composition may be obtained, for example, from reciprocal space mapping.

Embodiments May Include the Following Technical proposals:

### (Technical Proposal 1)

A semiconductor device, comprising:
a first electrode;
a second electrode;
a third electrode;
a fourth electrode, a second direction from the third electrode to the fourth electrode crossing a first direction from the first electrode to the second electrode;
a first terminal electrically connected to the third electrode;
a second terminal electrically connected to the fourth electrode;
a semiconductor member; and
a first insulating member,
at least a part of the semiconductor member being between the first electrode and the second electrode in the first direction,
the semiconductor member including:
   a first semiconductor region of a first conductivity type,
   a second semiconductor region of a second conductivity type,
   a third semiconductor region of the first conductivity type,
   a fourth semiconductor region of the second conductivity type, and
   a fifth semiconductor region of the second conductivity type,
the fourth semiconductor region being between the first electrode and the first semiconductor region in the first direction,
the second semiconductor region being between the first semiconductor region and the second electrode in the first direction,
the first semiconductor region including a first partial region, a second partial region, a third partial region, and a fourth partial region,
the first partial region being between the first electrode and the third electrode in the first direction,
a direction from the third electrode to the second partial region being along the second direction,
a direction from the third electrode to the second semiconductor region being along the second direction,
a direction from the third electrode to the third semiconductor region being along the second direction,
at least a part of the second semiconductor region being between the first semiconductor region and the third semiconductor region in the first direction,
the fifth semiconductor region being between the first partial region and the third electrode in the first direction,
the third partial region being between the first electrode and the fourth electrode in the first direction,
the direction from the fourth electrode to the fourth partial region being along the second direction,
the direction from the fourth electrode to the second semiconductor region being along the second direction,
the first insulating member including a first insulating region and a second insulating region,
the first insulating region being between the third electrode and the semiconductor member, and
the second insulating region being between the fourth electrode and the semiconductor member.

### (Technical Proposal 2)

The semiconductor device according to Technical proposal 1, wherein
the second insulating region is in contact with the third partial region and the fourth electrode in the first direction.
   (Technical proposal 3)

The semiconductor device according to Technical proposal 1, wherein
a plurality of the fourth electrodes are provided,
the first semiconductor region includes a plurality of the third partial regions,
one of the third partial regions is between the first electrode and one of the fourth electrodes in the first direction,
another one of the third partial regions is between the first electrode and another one of the fourth electrodes in the first direction,
the semiconductor member further includes a sixth semiconductor region of the second conductivity type,
the sixth semiconductor region is between the one of the plurality of third partial regions and the one of the plurality of fourth electrodes in the first direction, and
the sixth semiconductor region is not provided between the other one of the plurality of third partial regions and the other one of the plurality of fourth electrodes.

### (Technical Proposal 4)

The semiconductor device according to Technical proposal 3, wherein
a fifth semiconductor region thickness along the first direction of the fifth semiconductor region is thicker than a sixth semiconductor region thickness along the first direction of the sixth semiconductor region.

### (Technical Proposal 5)

The semiconductor device according to Technical proposal 3, wherein
a fifth impurity concentration of the second conductivity type in the fifth semiconductor region is higher than a sixth impurity concentration of the second conductivity type in the sixth semiconductor region.

### (Technical Proposal 6)

The semiconductor device according to Technical proposal 3, wherein
the sixth semiconductor region is continuous with the fifth semiconductor region.

### (Technical Proposal 7)

The semiconductor device according to any one of Technical proposals 1-3, wherein
the second electrode is electrically connected to the third semiconductor region.

### (Technical Proposal 8)

The semiconductor device according to any one of Technical proposals 1-3, further comprising:
a first conductive member,
a direction from the third electrode to the first conductive member being along the second direction,
the first semiconductor region further including a fifth partial region and a sixth partial region,
the fifth partial region being between the first electrode and the first conductive member in the first direction,
a direction from the first conductive member to the sixth partial region being along the second direction,
a direction from the first conductive member to the second semiconductor region being along the second direction,
the first insulating member including a third insulating region,
the third insulating region being between the first conductive member and the semiconductor member, and
the first conductive member being electrically connected to the second electrode.

### (Technical Proposal 9)

The semiconductor device according to Technical proposal 8, wherein
the semiconductor member further includes a seventh semiconductor region of the second conductivity type, and
the seventh semiconductor region is between the fifth partial region and the first conductive member.

### (Technical Proposal 10)

The semiconductor device according to Technical proposal 9, wherein
a fifth semiconductor region thickness along the first direction of the fifth semiconductor region is thicker than a seventh semiconductor region thickness along the first direction of the seventh semiconductor region.

### (Technical Proposal 11)

The semiconductor device according to Technical proposal 9, wherein
a fifth impurity concentration of the second conductivity type in the fifth semiconductor region is higher than a seventh impurity concentration of the second conductivity type in the seventh semiconductor region.

### (Technical Proposal 12)

The semiconductor device according to Technical proposal 9, wherein
the seventh semiconductor region is continuous with the fifth semiconductor region.
   (Technical proposal 13)

The semiconductor device according to any one of Technical proposals 1-12, wherein
the first insulating region is in contact with the fifth semiconductor region and the third electrode.

### (Technical Proposal 14)

The semiconductor device according to any one of Technical proposals 1-12, wherein
a part of the first semiconductor region is between the fifth semiconductor region and the first insulating region in the first direction.

### (Technical Proposal 15)

The semiconductor device according to any one of Technical proposals 1-14, further comprising:
a second conductive member,
the semiconductor member including a cell region and a peripheral region,
a direction from the cell region to the peripheral region crossing the first direction,
the third electrode and the fourth electrode being provided in the cell region,
the second conductive member being provided in the peripheral region,
the semiconductor member further including an eighth semiconductor region of the second conductivity type,
in the peripheral region, a part of the first semiconductor region being between the first electrode and the eighth semiconductor region in the first direction,
a direction from the second conductive member to the eighth semiconductor region crossing the first direction, and
the fifth semiconductor region being discontinuous with the eighth semiconductor region.

### (Technical Proposal 16)

The semiconductor device according to Technical proposal 15, wherein
a part of the first semiconductor region is between the fifth semiconductor region and the eighth semiconductor region.

### (Technical Proposal 17)

The semiconductor device according to Technical proposal 15 or 16, wherein
the first insulating member further includes a fourth insulating region, and
the fourth insulating region is provided between the second conductive member and the semiconductor member.

### (Technical Proposal 18)

The semiconductor device according to any one of Technical proposals 1-17, further comprising:
a second insulating member,
at least a part of the second insulating member being provided between the third electrode and the second electrode, and between the fourth electrode and the second electrode.

### (Technical Proposal 19)

The semiconductor device according to any one of Technical proposals 1-18, wherein
a third semiconductor region is not provided between the fourth electrode and the second semiconductor region.

### (Technical Proposal 20)

The semiconductor device according to any one of Technical proposals 1-19, wherein
an impurity concentration of the second conductivity type in the fifth semiconductor region is not less than 0.001 times and not more than 0.1 times a second impurity concentration of the second conductivity type in the second semiconductor region.

According to the embodiment, a semiconductor device is provided that can improve characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode;
a fourth electrode, a second direction from the third electrode to the fourth electrode crossing a first direction from the first electrode to the second electrode;
a first terminal electrically connected to the third electrode;
a second terminal electrically connected to the fourth electrode;
a semiconductor member; and
a first insulating member,
at least a part of the semiconductor member being between the first electrode and the second electrode in the first direction,
the semiconductor member including:
a first semiconductor region of a first conductivity type,
a second semiconductor region of a second conductivity type,
a third semiconductor region of the first conductivity type,
a fourth semiconductor region of the second conductivity type, and
a fifth semiconductor region of the second conductivity type,
the fourth semiconductor region being between the first electrode and the first semiconductor region in the first direction,
the second semiconductor region being between the first semiconductor region and the second electrode in the first direction,
the first semiconductor region including a first partial region, a second partial region, a third partial region, and a fourth partial region,
the first partial region being between the first electrode and the third electrode in the first direction,
a direction from the third electrode to the second partial region being along the second direction,
a direction from the third electrode to the second semiconductor region being along the second direction,
a direction from the third electrode to the third semiconductor region being along the second direction,
at least a part of the second semiconductor region being between the first semiconductor region and the third semiconductor region in the first direction,
the fifth semiconductor region being between the first partial region and the third electrode in the first direction,
the third partial region being between the first electrode and the fourth electrode in the first direction,
the direction from the fourth electrode to the fourth partial region being along the second direction,
the direction from the fourth electrode to the second semiconductor region being along the second direction,
the first insulating member including a first insulating region and a second insulating region,
the first insulating region being between the third electrode and the semiconductor member, and
the second insulating region being between the fourth electrode and the semiconductor member.

2. The semiconductor device according to claim 1, wherein
the second insulating region is in contact with the third partial region and the fourth electrode in the first direction.

3. The semiconductor device according to claim 1, wherein
a plurality of the fourth electrodes are provided,
the first semiconductor region includes a plurality of the third partial regions,
one of the third partial regions is between the first electrode and one of the fourth electrodes in the first direction,
another one of the third partial regions is between the first electrode and another one of the fourth electrodes in the first direction,
the semiconductor member further includes a sixth semiconductor region of the second conductivity type,
the sixth semiconductor region is between the one of the plurality of third partial regions and the one of the plurality of fourth electrodes in the first direction, and
the sixth semiconductor region is not provided between the other one of the plurality of third partial regions and the other one of the plurality of fourth electrodes.

4. The semiconductor device according to claim 3, wherein
a fifth semiconductor region thickness along the first direction of the fifth semiconductor region is thicker than a sixth semiconductor region thickness along the first direction of the sixth semiconductor region.

5. The semiconductor device according to claim 3, wherein
a fifth impurity concentration of the second conductivity type in the fifth semiconductor region is higher than a sixth impurity concentration of the second conductivity type in the sixth semiconductor region.

6. The semiconductor device according to claim 3, wherein
the sixth semiconductor region is continuous with the fifth semiconductor region.

7. The semiconductor device according to claim 1, wherein
the second electrode is electrically connected to the third semiconductor region.

8. The semiconductor device according to claim 1, further comprising:
a first conductive member,
a direction from the third electrode to the first conductive member being along the second direction,
the first semiconductor region further including a fifth partial region and a sixth partial region,
the fifth partial region being between the first electrode and the first conductive member in the first direction,
a direction from the first conductive member to the sixth partial region being along the second direction,
a direction from the first conductive member to the second semiconductor region being along the second direction,
the first insulating member including a third insulating region,
the third insulating region being between the first conductive member and the semiconductor member, and
the first conductive member being electrically connected to the second electrode.

9. The semiconductor device according to claim 8, wherein
the semiconductor member further includes a seventh semiconductor region of the second conductivity type, and
the seventh semiconductor region is between the fifth partial region and the first conductive member.

10. The semiconductor device according to claim 9, wherein
a fifth semiconductor region thickness along the first direction of the fifth semiconductor region is thicker than a seventh semiconductor region thickness along the first direction of the seventh semiconductor region.

11. The semiconductor device according to claim 9, wherein
a fifth impurity concentration of the second conductivity type in the fifth semiconductor region is higher than a seventh impurity concentration of the second conductivity type in the seventh semiconductor region.

12. The semiconductor device according to claim 9, wherein
the seventh semiconductor region is continuous with the fifth semiconductor region.

13. The semiconductor device according to claim 1, wherein
the first insulating region is in contact with the fifth semiconductor region and the third electrode.

14. The semiconductor device according to claim 1, wherein
a part of the first semiconductor region is between the fifth semiconductor region and the first insulating region in the first direction.

15. The semiconductor device according to claim 1, further comprising:
a second conductive member,
the semiconductor member including a cell region and a peripheral region,
a direction from the cell region to the peripheral region crossing the first direction,
the third electrode and the fourth electrode being provided in the cell region,
the second conductive member being provided in the peripheral region,
the semiconductor member further including an eighth semiconductor region of the second conductivity type,
in the peripheral region, a part of the first semiconductor region being between the first electrode and the eighth semiconductor region in the first direction,
a direction from the second conductive member to the eighth semiconductor region crossing the first direction, and
the fifth semiconductor region being discontinuous with the eighth semiconductor region.

16. The semiconductor device according to claim 15, wherein
a part of the first semiconductor region is between the fifth semiconductor region and the eighth semiconductor region.

17. The semiconductor device according to claim 15, wherein
the first insulating member further includes a fourth insulating region, and
the fourth insulating region is provided between the second conductive member and the semiconductor member.

18. The semiconductor device according to claim 1, further comprising:
a second insulating member,
at least a part of the second insulating member being provided between the third electrode and the second electrode, and between the fourth electrode and the second electrode.

19. The semiconductor device according to claim 1, wherein
a third semiconductor region is not provided between the fourth electrode and the second semiconductor region.

20. The semiconductor device according to claim 1, wherein
an impurity concentration of the second conductivity type in the fifth semiconductor region is not less than 0.001 times and not more than 0.1 times a second impurity concentration of the second conductivity type in the second semiconductor region.
